(19) United States
(12) Patent Application Publication
(10) Pub. No.: US 2008/0116520 A1
(43) Pub. Date: May 22, 2008

(54) Termination Structures For Semiconductor Devices and the Manufacture Thereof

(75) Inventor: Raymond J. Grover, Manchester (GB)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: Koninklijke Philips Electronics N.V., Eindhoven (NL)

(21) Appl. No.: 10/561,308

(22) PCT Filed: May 21, 2004
(86) PCT No.: PCT/IB04/01791

§ 371 Date: Jan. 17, 2008

(30) Foreign Application Priority Data
May 31, 2003 (GB) 0312514.3

(51) Int. Cl. H01L 27/06; H01L 21/8234

(52) U.S. Cl. 257/362; 438/237; 257/E21.616; 257/E27.016

(57) ABSTRACT

A semiconductor device has a semiconductor body (22) comprising an active area (7) and a termination structure (16) surrounding the active area. The termination structure comprises a plurality of lateral transistor devices (2a to 2d) connected in series and extending from the active area towards a peripheral edge (42) of the semiconductor body, with a zener diode (8) connected to the gate electrode (4) of one of the lateral devices for controlling its gate voltage, such that a voltage difference between the active area and the peripheral edge is distributed across the lateral devices and the zener diode. The termination structure (16) is capable of withstanding higher voltages in a compact manner and features thereof are susceptible to fabrication in the same process steps as features of the active area (7).

The present invention relates to field termination structures for semiconductor devices, for example insulated-gate field effect power transistors (commonly termed “MOSFETs”), or insulated-gate bipolar transistors (commonly termed “IGBTs”), and methods for the manufacture thereof.

Semiconductor devices generally include a semiconductor body comprising an active area which has an array of active structures therein. To avoid premature breakdown of the devices at the perimeter of the active area, it is often necessary to include a field termination structure surrounding the active area to avoid the occurrence excessively high electric fields. Several field termination structures are known in the art, such as floating field plates and floating field rings. These structures are discussed for example in “Power Semiconductor Devices”, 1996, by B. J. Baliga, at pages 81 to 113, the contents of which are hereby incorporated herein as reference material.

The present invention seeks to provide an improved termination structure which is capable of withstanding higher voltages in a compact manner.

The present invention provides a semiconductor device having a semiconductor body comprising an active area and a termination structure surrounding the active area, the termination structure comprising a plurality of lateral transistor devices connected in series and extending from the active area towards a peripheral edge of the semiconductor body, with a zener diode connected to the gate electrode of one of the lateral devices for controlling its gate voltage, such that a voltage difference between the active area and the peripheral edge is distributed across the lateral devices and the zener diode.

The incorporation of a zener diode into the termination structure in this way enables the voltage that may be withstood by the termination structure to be significantly increased.

Preferably, a zener diode is connected between each pair of adjacent lateral transistors. In a preferred embodiment, each of the zener diodes is connected between the source electrode of the lateral transistor of the corresponding pair closer to the active area and the gate electrode of the other lateral transistor of the corresponding pair. In an alternative embodiment, each zener diode is connected between the gate electrodes of the corresponding pair of lateral transistors.

Advantageously, the termination structure may have features formed in the same process steps as features in the active area of the device, avoiding the need for extra process steps to form features of the termination structure.

For example, each lateral device preferably comprises a gate electrode insulated from the semiconductor body by a layer of gate insulating material, the gate electrodes and layers of gate insulating material of the lateral devices being formed in the same respective process steps as insulated electrodes and layers of material insulating the insulated electrodes of devices in the active area.

The active area may comprise trench-gate semiconductor devices, and in this case, the lateral transistors of the termination structure are preferably trench-gate transistors. More particularly, each lateral device may comprise a trench having a gate electrode therein, the trenches of the lateral devices being formed in the same respective process steps as gate trenches of devices in the active area.

Alternatively, the active area may comprise planar gate semiconductor devices, with the lateral transistors of the termination structure being planar gate transistors.

The lateral devices may include a region of a first conductivity type over an underlying region of a second, opposite conductivity type, wherein the active area comprises devices having a region of the first conductivity type which is formed in the same process step as the first conductivity type region of the lateral devices.

Advantageously, in an embodiment where the gate electrodes of the lateral devices are formed of polycrystalline silicon, the zener diode is formed of polycrystalline silicon deposited in the same process step as the gate electrodes. For example, the zener diode may be of a lateral configuration and integrally formed with the gate electrode of the associated lateral device.

The invention further provides a method of forming a semiconductor device having a semiconductor body comprising an active area and a termination structure surrounding the active area, the termination structure comprising a plurality of lateral transistor devices connected in series and extending from the active area towards a peripheral edge of the semiconductor body, with a zener diode connected to the gate electrode of one of the lateral devices for controlling its gate voltage, such that a voltage difference between the active area and the peripheral edge is distributed across the lateral devices and the zener diode, wherein the gate electrodes of the lateral devices are formed of polycrystalline silicon, and the method comprises forming the zener diode of polycrystalline silicon deposited in the same process step as the gate electrodes.

In a preferred embodiment, each lateral device comprises a trench having the gate electrode therein, and the method comprises forming the trenches of the lateral devices in the same respective process steps as gate trenches of devices in the active area.

Embodiments of the invention will now be described by way of example and with reference to the accompanying schematic drawings, wherein:

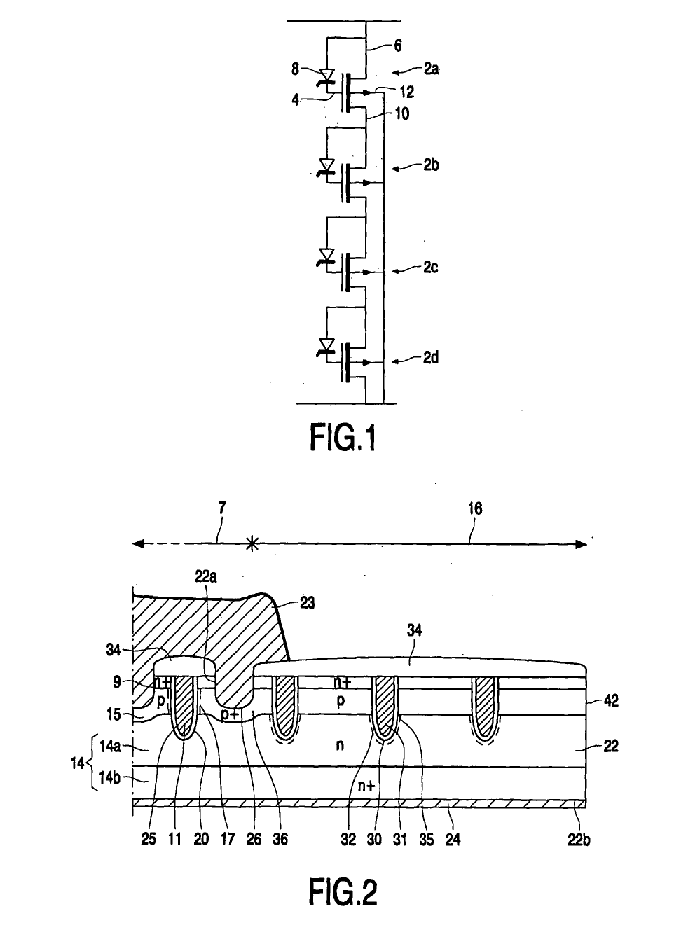

FIG. 1 shows a circuit diagram of transistor devices and zener diodes connected together in a termination structure in an embodiment of the invention;

FIG. 2 shows a cross-sectional view of the active area and termination structure of a trench-gate semiconductor device in accordance with the invention;

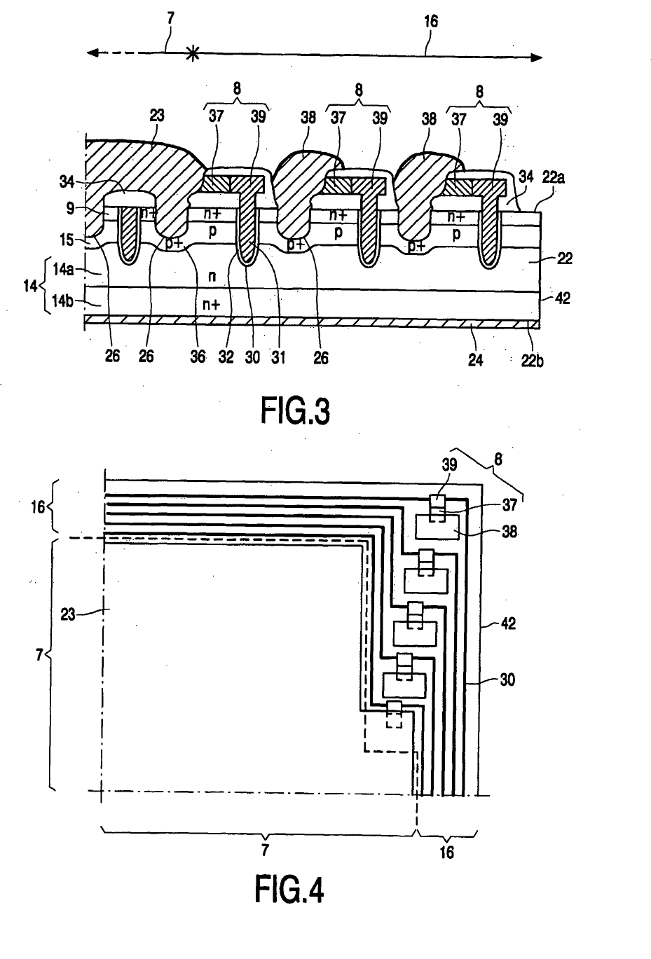

FIG. 3 shows a cross-sectional view of the active area and termination structure of a corner portion of the semiconductor device of FIG. 2;

FIG. 4 shows a plan view of the active area and termination structure of a corner portion of the semiconductor device of FIG. 2;

FIG. 5 shows a circuit diagram of transistor devices and zener diodes connected together in a termination structure in a further embodiment of the invention;

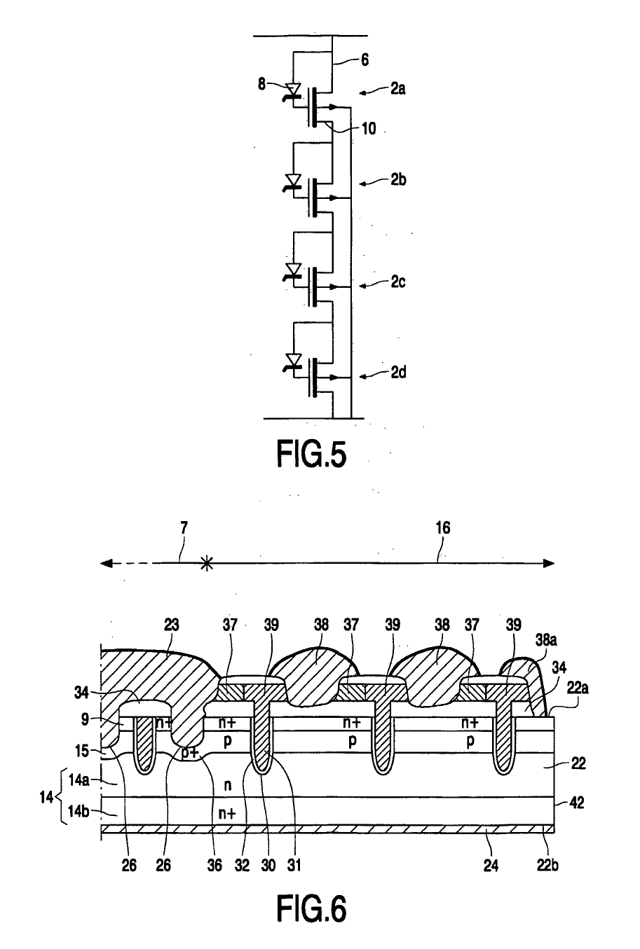

FIG. 6 shows a cross-sectional view of the active area and termination structure of a corner portion of a trench-gate semiconductor device including the configuration of FIG. 5;

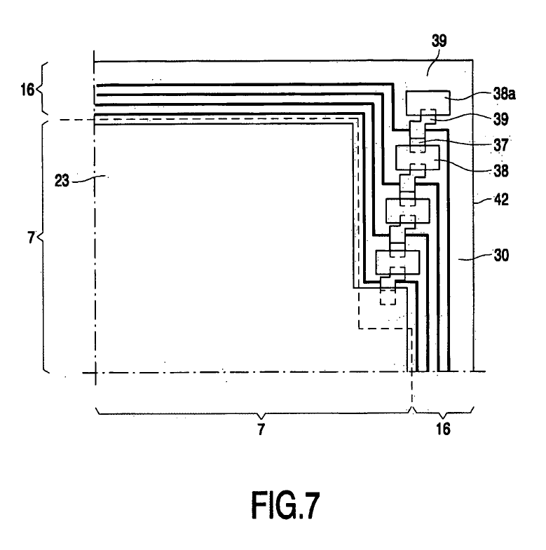

FIG. 7 shows a plan view of the active area and termination structure of a corner portion of the semiconductor device of FIG. 6;

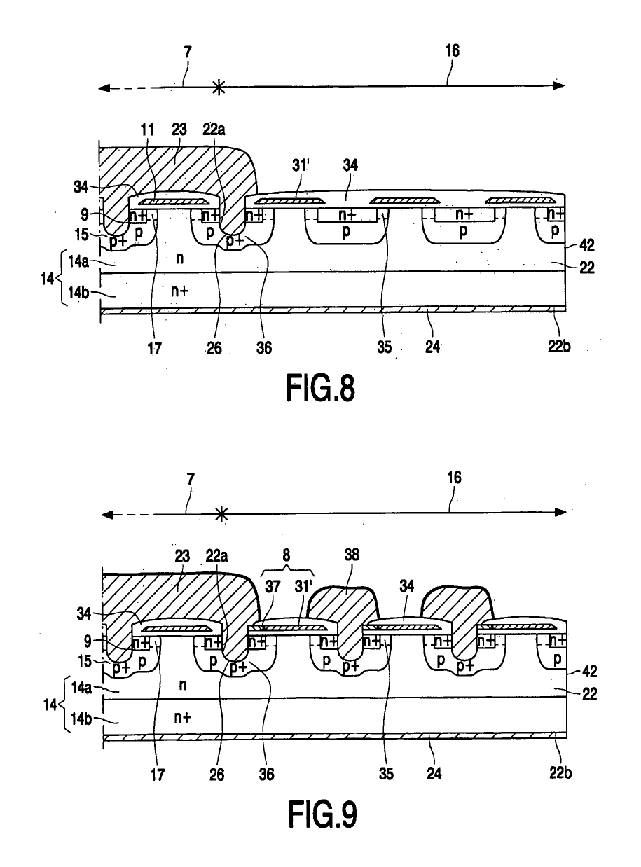

FIG. 8 shows a cross-sectional view of the active area and termination structure of a planar gate semiconductor device in accordance with the invention; and

FIG. 9 shows a cross-sectional view of the active area and termination structure of a corner portion of the semiconductor device of FIG. 8.

It should be noted that the Figures are diagrammatic and not drawn to scale. Relative dimensions and proportions of parts of these Figures have been shown exaggerated or reduced in size, for the sake of clarity and convenience in the drawings. The same reference signs are generally used to refer to corresponding or similar features in modified and different embodiments.

FIG. 1 shows a string of p-channel MOSFETs 2a to 2d connected together in series for use in a termination structure of a semiconductor device according to a first embodiment of the invention. A zener diode 8 is connected between each pair of adjacent lateral transistors. Each zener diode is connected between the source of the lateral transistor of the corresponding pair closer to the active area and the gate of the other lateral transistor of the corresponding pair. More particularly, in the embodiment of FIG. 1, each MOSFET has a zener diode 8 connected between its gate electrode 4 and drain electrode 6, orientated with its cathode connected to the gate electrode. The source electrode 10 of the first MOSFET 2a in the string is connected to the drain electrode of the next MOSFET 2b in the string, and so on along the string. The MOSFETs have a common body region and so their body terminals 12 are shown connected together. Four MOSFET and zener diode pairs are shown by way of example, but it will be appreciated that a different number of devices may be employed, depending on the voltage that is to be supported across the devices. In later cross-sectional drawings only three lateral devices are shown in the termination structure for clarity.

In a termination structure, one end of the string, that is the drain electrode of the first MOSFET 2a, is electrically connected to a first main electrode of the semiconductor device, the other end of the string, that is the source electrode 10 of the last MOSFET 2d, is electrically connected to a second main electrode of the semiconductor device.

With the MOSFETs and zener diodes of FIG. 1 connected together in the manner shown, each zener diode acts to control the gate voltage of the respective MOSFET, such that the MOSFET will turn on when the voltage across it and the associated zener diode is greater than its threshold voltage plus the zener voltage of the diode. The potential applied across the string of MOSFETs and diodes is divided thereacross, approximately uniformly distributing the associated electric field in the semiconductor body, thereby avoiding any field concentration leading to premature breakdown.

A cross-sectional view through a semiconductor device incorporating the termination arrangement illustrated in FIG. 1 is shown in FIG. 2.

The active area 7 of the device is shown on the left of the Figure, with a termination structure 16 on the right. By way of example, the active area illustrated comprises trench-gate transistor cells. Source and drain regions 9 and 14, respectively, of a first conductivity type (n-type in this example) are separated by a channel-accommodating region 15 of the opposite second conductivity type (i.e. p-type in this example) in a semiconductor body 22 (typically formed of monocrystalline silicon). The gate electrode 11, typically formed of n-type polycrystalline silicon, is present in a trench 20 which extends through the regions 9 and 15 into an underlying portion of the drain region 14. The gate electrode is separated from the semiconductor body by a layer of gate insulating material 25. The application of a voltage signal to the gate electrode 11 in the on-state of the device serves in known manner for inducing a conduction channel 17 in the region 15 and for controlling current flow in this conduction channel 17 between the source and drain regions 9 and 14.

The source region 9 is contacted by a first main electrode of the semiconductor device, embodied in this example by source electrode 23. This contact is made at a top major surface 22a of the device body. The illustrated example includes a “moated” source to device body contact in which a groove 26 is etched through the source region 9 to enable direct contact between the source electrode 23 and channel-accommodating region 15. Such a structure may enable the mask count of the device fabrication process to be reduced as a mask is not required to pattern implantation of the source region. An example of a method for manufacturing a trench-gate device having the configuration shown in the active area 7 of FIG. 2 is disclosed in EP-A-0889511, the contents of which are hereby incorporated herein as reference material.

By way of example, FIG. 2 shows a vertical device structure in which the region 14 comprise a drain-drift region 14a formed by an epitaxial layer of high resistivity (n−, low doping) on a substrate region 14b of high conductivity (n+). This substrate region 14b may be of the same conductivity type (n-type in this example) as the region 14a to provide a vertical MOSFET, or it may be of opposite conductivity type (p-type in this example) to provide a vertical IGBT. The substrate region 14b is contacted at the bottom major surface 22b of the device body by a second main electrode 24 of the semiconductor device, called the drain electrode in the case of a MOSFET and called the anode electrode in the case of an IGBT.

The termination structure shown in FIG. 2 comprises lateral trench-gate transistor cells. Each lateral device comprises a trench 30 having a gate electrode 31 therein separated from the semiconductor body 22 by a layer of gate insulating material 32. An insulating cap 34 extends over the top major surface 22a of the semiconductor body (restricted to the surface between the grooves 26 in the active area). In the on-state (although the lateral devices would not of course turn-on during normal operation of the device), a channel 35 would be formed in the drain-drift region 14a, extending between the p-type regions 15 on either side of the trench 30. In the illustrated example, the channel 35 would be formed of p-type charge carriers.

The drain region of the lateral device adjacent to the active area is connected to the source electrode 23. The source region of the outermost lateral device may be shorted to the drain electrode 24 by the rough surface of peripheral edge 42 formed in cutting the semiconductor body 22 from a wafer. Alternatively, region 15 may be connected to the drain electrode 24 by an additional conductive connector extending over the surface of the semiconductor body.

It can be seen in FIG. 2 that the trenches 30, gate insulating material layer 32, and gate electrode 31 features of the termination structure correspond in configuration with the trenches 20, gate insulating material layer 25, and gate electrodes 11 of the active area. They may be efficiently fabricated in the same process steps as the corresponding active area features, avoiding the need for extra steps to form these elements of the termination structure.

The highly doped first conductivity type region 9 which forms the source regions of the devices in the active area 7 is shown in FIG. 2 (and later Figures) as continuing through the termination structure 16. Alternatively, the termination structure area may be masked during implantation to form this region. In the embodiment of FIG. 2 this is a blanket implantation, so masking the termination structure area will require an additional mask.

As shown in FIG. 1, the gate electrodes of the lateral transistors in the termination structure are connected to the respective drain electrodes by zener diodes 8. An implementation of this aspect is shown in FIG. 3. The gate electrode material is extended out of the trench 30 forming an extension 39. The gate extension 39 (of n-type polycrystalline silicon in this example) is in contact with a layer of p-type polycrystalline silicon 37, forming a zener diode 8 therewith. The p-type polycrystalline silicon layer 37 is in turn electrically connected to p-type region 15 of the semiconductor body at the surface of groove 26 by a metal strap 38, except for the zener diode associated with the lateral device closest to the active area, for which this connection is made by the source electrode 23.

The polycrystalline silicon forming layer 37 and the extension 39 may be provided for example by suitably masking the polycrystalline silicon material deposited to fill the gate trenches, during etching back of this material to leave it level with the top of the trenches in the active area. In one approach, the deposited polycrystalline silicon is in-situ doped n-type and the layer 37 is then defined by a p-type implant or diffusion through a suitable mask. Alternatively, the deposited polycrystalline silicon may be in-situ doped p-type and then the layer 37 masked during a n-type implant or diffusion. In another approach, the deposited polycrystalline silicon may be undoped and then doped n or p type by appropriately masked implantation or diffusion steps to form elements 37 and 39.

In a further variation, the extension 39 may be provided by a suitable series of deposition, doping (if the material is not in-situ doped) and etching steps, and the layer 37 formed by a separate series of these steps.

To avoid the need for an additional dedicated process step, the metal straps 38 (and 38a in FIG. 6) may be formed in the termination structure in the same process steps as the source electrode, in this embodiment and those discussed below.

As shown in FIGS. 2, 3 and 6, a p-type region 36 may be included in the channel-accommodating region 15 between the source regions 9 adjacent the top major surface 22a, which is more highly doped than the channel-accommodating region 15. These regions may be formed by implantation through windows of an appropriate mask. These regions serve in a known manner to give a good contact between the channel-accommodating region 15 and the source electrode 23. They may also be included in the termination structure in the embodiment of FIG. 3 to enhance the contact between the region 15 and the metal straps 38. The regions 36 may also extend more deeply than the channel-accommodating region 15 in the active area and/or the termination structure to reduce the electric field near the bottom of the adjacent trenches.

The area occupied by the termination structure may be minimised by having a close trench spacing in the majority of the structure and only increasing the spacing where necessary to allow for the polycrystalline layer 37 and the metal straps 38. For example, as shown schematically in FIG. 4, the zener diodes 8 may be located towards one corner of the semiconductor body, adjacent to the peripheral edge 42 of the semiconductor body. Features of the semiconductor device overlying the elements depicted in FIG. 4 are not shown for the purposes of illustration. In the example of FIG. 4, five trenches 30 of stripe geometry surround the active area 7 in the termination structure 16. The trenches of the active area 7 may also have a stripe geometry. It will be appreciated that other geometries may be used for the active area, such as square or close-packed hexagonal geometries, for example.

An alternative configuration to that of FIG. 1 is illustrated in FIG. 5. In this example, each zener diode 8 is connected between the gates of the corresponding pair of adjacent lateral transistors in the string. That is, the cathode of the first zener diode is connected to the gate of transistor 2d, and its anode is connected to the gate of transistor 2c, and so on. A further diode has its cathode connected to the gate of transistor 2a and its anode connected to the first main electrode of the semiconductor device. The gate of transistor 2d is connected to the second main electrode of the semiconductor device.

In the configuration of FIG. 5, the string of transistors and diodes is able to support a maximum voltage drop of 4 times the zener voltage of the diodes.

A cross-sectional view through a semiconductor device incorporating the termination arrangement illustrated in FIG. 5 is shown in FIG. 6. The cross-section is through the area where the zener diodes are provided. A cross-section at a location in the remainder of the termination structure could be the same as FIG. 2 above, for example. In a similar manner to the embodiment of FIG. 3, the metal strap 38 is in contact with n-type polycrystalline silicon layer 37. In contrast to FIG. 3, the metal strap 38 of FIG. 6 is also in contact with the gate electrode extension 39 of the adjacent lateral transistor on the side closer to the active area 7, and insulated from the p-type region 15 of the semiconductor body. The metal straps 38 serve here to connect the string of zener diodes together (rather than continuing n-type polycrystalline silicon layer 37 to meet the gate extension 39 of the adjacent transistor as this would form back to back zener diodes).

A further metal strap 38a is provided in the embodiment of FIG. 6 to provide an electrical connection between the gate electrode of the outermost lateral device and its source region. The source region is in turn shorted to the drain region here by the process of cutting the edge 42 (or an additional conductive connector may provide this connection).

FIG. 7 is a plan view of a corner portion a semiconductor body, according to the embodiment of FIG. 6, illustrating the configuration of the zener diodes in the termination structure 16. In this example, four trenches of stripe geometry surround the active area 7 of the device in the termination structure. Like FIG. 4, features of the semiconductor device overlying the elements depicted in FIG. 7 are not shown for the purposes of illustration.

In a typical example of the devices shown in FIG. 2, the pitch of the lateral devices in the termination structure 16 is 2.4 microns, and the trench width is 0.5 microns. The gate insulating layer 25 is a 40 nm layer of silicon dioxide, the n-type region 14a has a doping level of 1×10¹⁶ phosphorus or arsenic atoms per cm³, and the p-type region has a doping level of 1×10¹⁷ boron atoms per cm³. The gate electrode is formed of n-type polycrystalline silicon with a doping level of 1×10²⁰ phosphorus atoms per cm³.

In the zener diodes shown in FIGS. 3 and 6, the p-type doping level of polycrystalline silicon layer 37 may typically be 1×10¹⁹ boron atoms per cm³. Thus, in this example, the polycrystalline silicon forming elements 37 and 39 may be initially uniformly doped p-type to this level, and then layer 37 masked during addition of n-type dopant at the concentration of 1×10²⁰ phosphorus atoms per cm³ such that the p-type dopant is overdoped in element 39. It will be appreciated that the doping levels of elements 37 and 39 may be varied to adjust the zener voltage of the resulting diode to some extent.

In order to accommodate the zener diodes 8 shown in FIGS. 3 and 6, the pitch of the lateral devices may be increased locally to around 15 microns for example.

In an example of the structure shown in FIG. 3, with the parameters given above, the transistor adjacent the peripheral edge 42 of the device will have a threshold voltage of around 2.3V, and the zener voltage is about 7.5V. The transistor and diode combination will therefore start to conduct at around 9.8V (or slightly above this value), and will transfer this voltage to the source of the adjacent lateral device. This will therefore have a back bias between its source and region 14a, increasing its threshold voltage to around 3.8V. The voltage that may be supported across the second transistor and diode pair is therefore around 11.3V, and so on along the string of lateral devices and diodes. With a string of 4 pairs of devices, the termination structure will be able to withstand around 45V. As the pitch of the lateral devices is 2.4 microns, only 9.6 microns will be required to accommodate the termination structure.

In the embodiment of FIG. 5, the voltage that may be dropped across the string of lateral devices and zener diodes is equal to the sum of the zener voltages of the zener diodes. For example, employing the parameters described above, a string of four zener diodes would drop a voltage of up to 30V.

The trench-gate devices in the active area of the embodiments described above have a moated source configuration. It will be appreciated that the invention is equally applicable to configurations in which instead the implant forming the source region is masked. In that case, the implant is masked such that the source regions adjacent each trench are spaced apart to allow metal straps 38 in the termination structure to contact p-type region 15 at the top major surface 22a of the semiconductor body.

The invention is applicable to planar gate devices as well as trench-gate devices. Cross-sections of a planar gate device embodying the invention are shown in FIGS. 8 and 9 by way of illustration. These views are similar to those of FIGS. 2 and 3, respectively, and like FIGS. 2 and 3, show an embodiment having a moated source contact in the active area and zener diodes configured in the termination structure in accordance with FIG. 1. As shown in FIG. 9, planar gate electrodes 31′ (of n-type polycrystalline silicon in this example) extend over the semiconductor body 22 and form zener diodes 8 with adjoining respective p-type polycrystalline silicon layers 37.

Although the invention is described above in devices having MOSFETs in the active area, it will be apparent that the termination structure may also be employed in a range of other devices, such as IGBTs, thyristors, or rectifiers, for example. It is particularly beneficial and susceptible to application where the devices of the active area include features which may be formed in the same process steps as features of the termination structure.

It will be appreciated that where specific conductivity types are referred to in the examples above, it is within the scope of the invention for the conductivity types to be reversed, with references to n-type being replace by p-type and vice versa. In the examples depicted in the drawings the active devices are n-channel devices, in which the regions 9 and 14 are of n-type conductivity, the region 15 is of p-type, and an electron inversion channel 17 is induced in the region 15 by the gate electrode 11. By using opposite conductivity type dopants, these devices are instead p-channel devices. In this case, the regions 9 and 14 are of p-type conductivity, the region 15 is of n-type, and a hole inversion channel 17 is induced in the region 15 by the gate electrode 11. Furthermore, in this embodiment, the channel 35 that would be in principle be induced in the termination structure if the lateral devices turned on would be an electron inversion channel in p-type region 14a.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this application to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

1. A semiconductor device having a semiconductor body (22) comprising an active area (7) and a termination structure (16) surrounding the active area, the termination structure comprising a plurality of lateral transistor devices (2a to 2d) connected in series and extending from the active area towards a peripheral edge (42) of the semiconductor body, with a zener diode (8) connected to the gate electrode (4) of one of the lateral devices for controlling its gate voltage, such that a voltage difference between the active area and the peripheral edge is distributed across the lateral devices and the zener diode.

2. A semiconductor device of claim 1 wherein a zener diode (8) is connected between each pair of adjacent lateral transistors (2a to 2d).

3. A semiconductor device of claim 2 wherein each zener diode (8) is connected between the source electrode (10) of the lateral transistor of the corresponding pair closer to the active area (7) and the gate electrode (4) of the other lateral transistor of the corresponding pair.

4. A semiconductor device of claim 2 wherein each zener diode (8) is connected between the gate electrodes (4) of the corresponding pair of lateral transistors.

5. A semiconductor device of any preceding claim wherein each lateral device (2a to 2d) comprises a gate electrode (31) insulated from the semiconductor body (22) by a layer (32) of gate insulating material, the gate electrodes and layers of gate insulating material of the lateral devices being formed in the same respective process steps as insulated electrodes (11) and layers (25) of material insulating the insulated electrodes of devices in the active area (7).

6. A semiconductor device of claim 5 wherein the active area (7) comprises trench-gate semiconductor devices and the lateral transistors of the termination structure (16) are trench-gate transistors.

7. A semiconductor device of claim 5 or claim 6 wherein each lateral device (2a to 2d) comprises a trench (30) having the gate electrode (31) therein, the trenches of the lateral devices being formed in the same respective process steps as gate trenches (20) of devices in the active area (7).

8. A semiconductor device of claim 5 wherein the active area (7) comprises planar gate semiconductor devices and the lateral transistors of the termination structure (16) are planar gate transistors.

9. A semiconductor device of any preceding claim wherein the lateral devices (2a to 2d) include a region (15) of a first conductivity type over an underlying region (14a) of a second, opposite conductivity type, and wherein the active area (7) comprises devices having a region (15) of the first conductivity type which is formed in the same process step as the first conductivity type region of the lateral devices.

10. A semiconductor device of any preceding claim wherein the gate electrodes (31) of the lateral devices are formed of polycrystalline silicon, and the zener diode (8) is formed of polycrystalline silicon deposited in the same process step as the gate electrodes.

11. A method of forming a semiconductor device having a semiconductor body (22) comprising an active area (7) and a termination structure (16) surrounding the active area, the termination structure comprising a plurality of lateral transistor devices (2a to 2d) connected in series and extending from the active area towards a peripheral edge (42) of the semiconductor body, with a zener diode (8) connected to the gate electrode (4) of one of the lateral devices for controlling its gate voltage, such that a voltage difference between the active area and the peripheral edge is distributed across the lateral devices and the zener diode, wherein the gate electrodes (31) of the lateral devices are formed of polycrystalline silicon, and the method comprises forming the zener diode (8) of polycrystalline silicon deposited in the same process step as the gate electrodes.

12. A method of claim 11 wherein each lateral device (2a to 2d) comprises a trench (30) having the gate electrode (31) therein, and the method comprises forming the trenches of the lateral devices in the same respective process steps as gate trenches (20) of devices in the active area (7).

13. A semiconductor device substantially as described herein with reference to the accompanying Drawings.

14. A method of forming a semiconductor device substantially as described herein with reference to the accompanying Drawings.
